(19) United States
(12) Patent Application Publication
(10) Pub. No.: US 2013/0050552 A1
(43) Pub. Date: Feb. 28, 2013

(54) SOLID-STATE IMAGING APPARATUS, METHOD OF MANUFACTURING SOLID-STATE IMAGING APPARATUS, AND ELECTRONIC APPARATUS

(71) Applicant: Tetsuya Oishi, Kanagawa (JP)

(72) Inventor: Tetsuya Oishi, Kanagawa (JP)

(73) Assignee: Sony Corporation, Tokyo (JP)

(21) Appl. No.: 13/566,714

(22) Filed: Aug. 3, 2012

(30) Foreign Application Priority Data
Aug. 24, 2011 (JP) 2011-182429

(51) Int. Cl. H01L 27/146; H04N 5/335; H01L 31/18

(52) U.S. Cl. 348/301; 257/292; 438/73; 257/E27.133; 257/E31.053; 348/E05.091

(57) ABSTRACT

A solid-state imaging apparatus includes: photoelectric conversion sections that generate signal charge corresponding to an amount of received light; and a plurality of pixel transistors that read the signal charge generated in the photoelectric conversion sections, and include amplification transistors each being formed of an amplification gate electrode which is formed on a substrate, a high-concentration impurity region which is formed in a substrate region on a drain side of the amplification gate electrode, and a low-concentration impurity region which is formed to have an impurity concentration lower than that of the high-concentration impurity region and is formed on a substrate region on a source side of the amplification gate electrode.

### FIELD

The present disclosure relates to a CMOS solid-state imaging apparatus and a manufacturing method thereof. In addition, the present disclosure also relates to an electronic apparatus using the solid-state imaging apparatus.

### BACKGROUND

Solid-state imaging apparatuses are roughly classified into CCD (Charge Coupled Device) solid-state imaging apparatuses and CMOS (Complementary Metal Oxide Semiconductor) solid-state imaging apparatuses. When the CCD solid-state imaging apparatus and the CMOS solid-state imaging apparatus are compared, in the CCD solid-state imaging apparatus, since a high driving voltage is necessary to transfer signal charge, in comparison with the CMOS solid-state imaging apparatus, an increase in a power supply voltage is necessary. As described above, in terms of power consumption and the like, the CMOS solid-state imaging apparatus is more advantageous than the CCD solid-state imaging apparatus.

Accordingly, recently, as solid-state imaging apparatuses mounted on mobile apparatuses such as camera-equipped mobile phones or PDAs (Personal Digital Assistant), the CMOS solid-state imaging apparatuses which are more advantageous than the CCD solid-state imaging apparatuses have come into widespread use.

The CMOS solid-state imaging apparatus includes: a light receiving section formed of a photodiode that generates signal charge in response to received light; a floating diffusion section from which the signal charge generated in the light receiving section is read; and a plurality of MOS transistors. Examples of the plurality of MOS transistors include transfer transistors, reset transistors, amplifier transistors, and selection transistors, and such MOS transistors are connected to a desired wiring layer of a multilayer wiring layer formed on the upper layer. In the CMOS solid-state imaging apparatus, the signal charge, which is generated and accumulated in the light receiving section, is read by the floating diffusion section through the transfer transistor for each pixel. Then, the signal charge, which is read using the floating diffusion section, is amplified by the amplification transistor, and is selectively output to a vertical signal line, which is formed on the multilayer wiring layer, by the selection transistor.

In such CMOS solid-state imaging apparatus, the MOS transistors constituting a pixel employ an LDD structure in order to improve the short channel effect resulting from a reduction in gate length (JP-A-2010-56516). FIG. 23 shows an exemplary configuration of a cross-section of pixel transistors in an existing solid-state imaging apparatus. FIG. 23 shows a reset transistor Tr1, an amplification transistor Tr2, and a selection transistor Tr3.

As shown in FIG. 23, in the existing solid-state imaging apparatus, each of the pixel transistors Tr1 to Tr3 includes: a gate electrode 101 that is formed on the surface of a substrate 100 with a gate insulation film 103 interposed therebetween; and source and drain regions which are formed in substrate regions with the gate electrode 101 interposed therebetween. Side walls 102 are formed of an insulation film on sides of the gate electrode 101. Further, the source and drain regions include low-concentration impurity regions 104 and high-concentration impurity regions 105 which are formed in order from the gate electrode 101 side.

After the gate electrode 101 is formed, the low-concentration impurity regions 104 are formed by ion-implanting impurity, of which a conductivity type is inverse to that of the impurity regions constituting the substrate 100, at a low concentration. On the other hand, after the side walls 102 are formed, the high-concentration impurity regions 105 are formed by ion-implanting impurity, of which a conductivity type is inverse to that of the impurity regions constituting the substrate 100, at a concentration higher than that of the low-concentration impurity regions 104.

Generally, in the MOS transistor having the LDD structure, the source region is formed to be symmetric to the drain region with the gate electrode 101 interposed therebetween. That is, both the source region and the drain region include the low-concentration impurity regions 104 and the high-concentration impurity regions 105 which are formed in order from the gate electrode 101 side.

### SUMMARY

Incidentally, recently in the CMOS solid-state imaging apparatus, the number of pixels is being increased in order to obtain a high-quality image, and the size thereof is being decreased to cope with the demand for a reduction in costs. Further, although the size of pixels is reduced, there is demand to secure a regular saturated charge quantity (Qs), and thus it is difficult to reduce the area for the photodiode. Therefore, there has been an increase in the demand to reduce the size of the active region in which the amplification transistor, the reset transistor, the selection transistor, and the like are formed. In this case, the reduction in area of the amplification transistor causes an increase in 1/f noise, and an increase in RTS (Random Telegraph Signal), thereby causing an increase in random noise and deterioration in imaging characteristics.

In view of the above situation, it is desirable to provide a solid-state imaging apparatus capable of achieving a reduction in random noise. It is also desirable to provide an electronic apparatus capable of improving image quality by providing the solid-state imaging apparatus.

An embodiment of the present disclosure is directed to a solid-state imaging apparatus including: photoelectric conversion sections that generate signal charges corresponding to an amount of received light; and a plurality of pixel transistors that read the signal charges generated in the photoelectric conversion sections. Among the pixel transistors, the amplification transistor includes an amplification gate electrode which is formed on a substrate, and impurity regions which are formed in substrate regions on a drain side and a source side of the amplification gate electrode. The impurity region, which is formed on the drain side of the amplification gate electrode includes a high-concentration impurity region. Further, the impurity region, which is formed on the source side of the amplification gate electrode includes a low-concentration impurity region which is formed to have an impurity concentration lower than that of the high-concentration impurity region formed on the drain side.

In the solid-state imaging apparatus according to the embodiment of the present disclosure, the low-concentration impurity region is not formed on the drain side of the amplification transistor, and thus it is possible to increase the effective gate length. Furthermore, since the source side of the amplification transistor is formed as the low-concentration impurity region, it is possible to suppress potential fluctuation on the substrate surface on the source side of the amplification gate electrode.

Another embodiment of the present disclosure is directed to a method of manufacturing the solid-state imaging apparatus including forming gate electrodes that constitute the plurality of pixel transistors on a substrate. The method also includes forming a resist mask that covers substrate regions on drain sides of amplification gate electrodes, which constitute amplification transistors among the plurality of pixel transistors, such that at least substrate regions on source sides of the amplification gate electrodes are open. The method further includes forming low-concentration impurity regions by ion-implanting impurity, of which a conductivity type is inverse to that of the substrate, through the resist mask. The method further includes forming side walls on sides of the gate electrodes by removing the resist mask. Further, the method includes forming high-concentration impurity regions, which are impurity regions with a concentration higher than that of the low-concentration impurity regions, by ion-implanting impurity, of which a conductivity type is inverse to that of the substrate, into the substrate regions on the source sides and the drain sides of the gate electrodes constituting the plurality of pixel transistors.

In the method of manufacturing the solid-state imaging apparatus according to the embodiment of the present disclosure, the drain side of each amplification transistor is formed by only the high-concentration impurity region. Further, before the side walls are formed, the low-concentration impurity region is formed on the source side of the amplification transistor. Hence, since the low-concentration impurity region is not formed under the side wall which is the drain side, it is possible to increase the effective gate length. Further, since the low-concentration impurity region is formed under the side wall which is the source side, it is possible to suppress potential fluctuation on the substrate surface on the source side of the amplification gate electrode.

Still another embodiment of the present disclosure is directed to an electronic apparatus including: an optical lens; the above-mentioned solid-state imaging apparatus into which the light concentrated by the optical lens is incident; and a signal processing circuit that processes an output signal which is output from the solid-state imaging apparatus.

According to the embodiments of the present disclosure, it is possible to obtain a solid-state imaging apparatus capable of achieving a reduction in 1/f noise and RTS without changing the areas of the gate electrodes of the amplification transistors. Further, it is possible to obtain an electronic apparatus capable of improving image quality using the solid-state imaging apparatus.

### BRIEF DESCRIPTION OF THE DRAWINGS

FIG. 1 is a schematic configuration diagram illustrating an overall CMOS solid-state imaging apparatus according to a first embodiment of the present disclosure;

FIG. 2 is an equivalent circuit diagram of a pixel constituting the solid-state imaging apparatus according to the first embodiment of the present disclosure;

FIG. 3 is a planar layout diagram of a unit pixel of the solid-state imaging apparatus according to the first embodiment of the present disclosure;

FIG. 4 is a diagram illustrating a cross-sectional configuration taken along line A-A of FIG. 3;

FIGS. 5A to 5D are process diagrams illustrating a method of manufacturing the solid-state imaging apparatus according to the first embodiment of the present disclosure;

FIG. 6 is a diagram of a planar configuration in a case where a resist mask for forming a low-concentration impurity region is formed on a semiconductor substrate in the first embodiment;

FIG. 7 is a diagram illustrating an experimental result of comparison of 1/f noises obtained when configurations of source and drain regions of an amplification transistor are respectively changed;

FIG. 8 is a cross-sectional configuration diagram of a solid-state imaging apparatus according to a modified example;

FIG. 9 is a planar layout diagram of a unit pixel of the solid-state imaging apparatus according to a second embodiment of the present disclosure; FIG. 10 is a diagram illustrating a cross-sectional configuration taken along line B-B of FIG. 9;

FIG. 11 is a diagram illustrating the method of manufacturing the solid-state imaging apparatus according to the first embodiment of the present disclosure;

FIG. 12 is a diagram of a planar configuration in a case where a resist mask for forming a low-concentration impurity region is formed on a semiconductor substrate in the second embodiment;

FIG. 13 is a diagram illustrating an example of a layout for widening an opening area of an opening portion of a resist mask in the solid-state imaging apparatus according to the second embodiment of the present disclosure;

FIG. 14 is a planar layout diagram of a unit pixel of a solid-state imaging apparatus according to a third embodiment of the present disclosure;

FIG. 15 is a diagram illustrating a cross-sectional configuration taken along line C-C of FIG. 14;

FIG. 16 is a diagram illustrating an example of a layout for widening an opening area of an opening portion of a resist mask in the solid-state imaging apparatus according to the third embodiment of the present disclosure;

FIG. 17 is a diagram of a planar configuration in a case where the resist mask for forming a low-concentration impurity region is formed on a semiconductor substrate in the third embodiment;

FIG. 18 is a planar layout diagram of a unit pixel of a solid-state imaging apparatus according to a fourth embodiment of the present disclosure;

FIG. 19 is a diagram illustrating a cross-sectional configuration taken along line D-D of FIG. 18;

FIG. 20 is a diagram illustrating an example of a layout for widening an opening area of an opening portion of a resist mask in the solid-state imaging apparatus according to the fourth embodiment of the present disclosure;

FIG. 21 is a diagram of a planar configuration in a case where the resist mask for forming a low-concentration impurity region is formed on a semiconductor substrate in the fourth embodiment;

FIG. 22 is a schematic configuration diagram of an electronic apparatus according to a fifth embodiment of the present disclosure; and

FIG. 23 is a diagram illustrating a cross-sectional configuration of a pixel transistors of an existing solid-state imaging apparatus.

### DETAILED DESCRIPTION

Hereinafter, an example of a solid-state imaging apparatus, a manufacturing method thereof, and an electronic apparatus having the solid-state imaging apparatus according to embodiments of the present disclosure will be described with reference to the accompanying drawings. The embodiments of the present disclosure will be described in order of the following items. Note that, the present disclosure is not limited to examples to be described hereinafter.

1. First Embodiment: Solid-State Imaging Apparatus
1-1 Overall Configuration
1-2 Configuration of Principal Section
1-3 Manufacturing Method

2. Second Embodiment: Solid-State Imaging Apparatus

3. Third Embodiment: Solid-State Imaging Apparatus

4. Fourth Embodiment: Solid-State Imaging Apparatus

5. Fifth Embodiment: Electronic Apparatus

### 1. First Embodiment: Solid-State Imaging Apparatus

### [1-1 Overall Configuration]

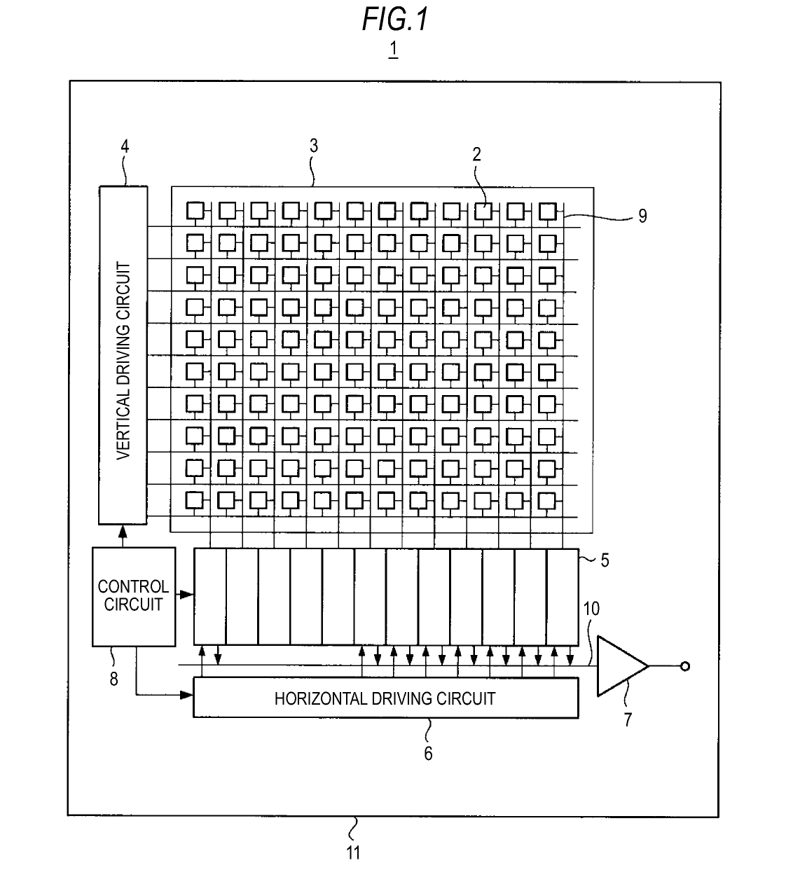

FIG. 1 is a schematic configuration diagram illustrating an overall CMOS solid-state imaging apparatus according to a first embodiment of the present disclosure.

The solid-state imaging apparatus 1 of the present embodiment includes a pixel region 3 formed of a plurality of pixels 2 arrayed on a substrate 11 made of silicon, a vertical driving circuit 4, column signal processing circuits 5, a horizontal driving circuit 6, an output circuit 7, a control circuit 8, and the like.

Each pixel 2 includes a photoelectric conversion section formed of a photodiode and a plurality of pixel transistors, and the plurality of pixels 2 are regularly arranged in a two dimensional array on the substrate 11. The pixel transistors constituting the pixel 2 may be four MOS transistors including a transfer transistor, a reset transistor, a selection transistor, and an amplifier transistor or three transistors excluding the selection transistor.

The pixel region 3 includes the plurality of pixels regularly arranged in the form of a two dimensional array. The pixel region 3 includes an effective pixel region in which signal charges generated through photoelectric conversion as a result of actually receiving light are amplified and from which the amplified signal charges are read by the column signal processing circuits and a reference black pixel region (not shown) for outputting optical black as the reference of a black level. The reference black pixel region is normally formed on the outer periphery of the effective pixel region.

The control circuit 8 generates a clock signal, a control signal, and the like used as the reference of operations of the vertical driving circuit 4, the column signal processing circuits 5, the horizontal driving circuit 6, and the like, on the basis of a vertical synchronizing signal, a horizontal synchronizing signal, and a master clock. Then, the clock signal, the control signal, and the like generated in the control circuit 8 are input into the vertical driving circuit 4, the column signal processing circuits 5, the horizontal driving circuit 6, and the like.

The vertical driving circuit 4 includes, for example, a shift register and selectively scans the respective pixels 2 in the pixel region 3 sequentially row by row in the vertical direction. The pixel signals based on signal charges, which are generated in response to amounts of light received in the photodiodes of the respective pixels 2, are supplied to the column signal processing circuits 5 through the vertical signal lines 9.

The column signal processing circuit 5 is disposed, for example, for each column of the pixels 2, and performs signal processing, such as noise removal and signal amplification, on signals, which are output from the pixels 2 in a single row, using a signal from the reference black pixel region (not shown but formed on the periphery of the effective pixel region) pixel column by pixel column. A horizontal selection switch (not shown) is provided between the output terminal of each column signal processing circuit 5 and a horizontal signal line 10.

The horizontal driving circuit 6 includes, for example, a shift register and sequentially selects the respective column signal processing circuits 5 by sequentially outputting horizontal scan pulses, so that the respective column signal processing circuits 5 output pixel signals to the horizontal signal line 10.

The output circuit 7 performs signal processing on the signals supplied sequentially from the respective column signal processing circuits 5 via the horizontal signal line 10, and outputs the signals.

### [1-2 Configuration of Principal Portion]

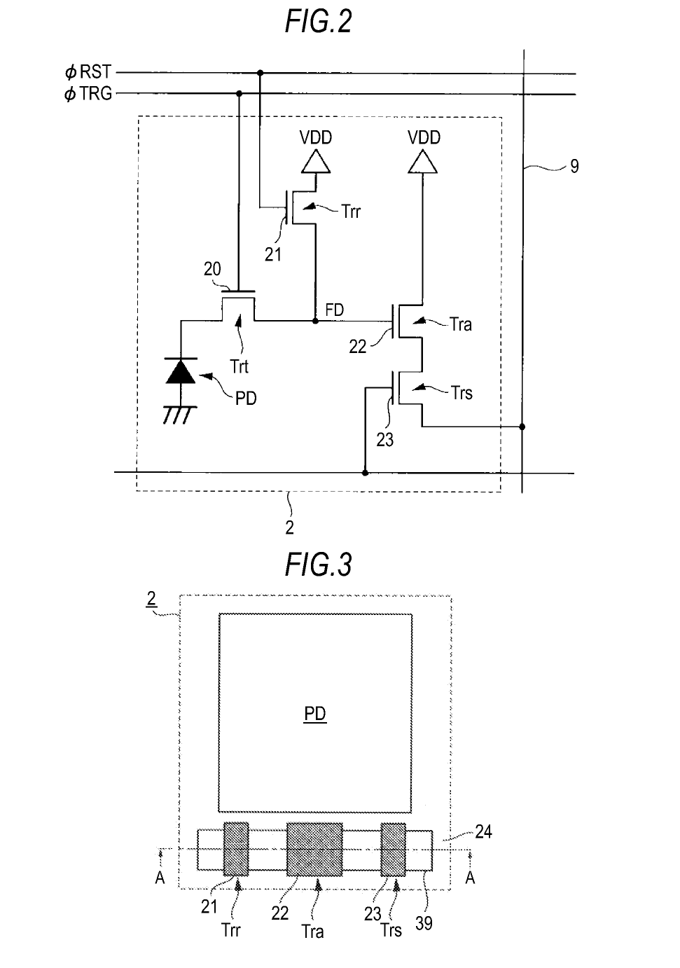

FIG. 2 is an equivalent circuit diagram of a pixel constituting the solid-state imaging apparatus according to the present embodiment. The unit pixel 2 of the solid-state imaging apparatus 1 according to the present embodiment includes: a photodiode PD as a photoelectric conversion device; a transfer transistor Trt; a reset transistor Trr; an amplification transistor Tra; and a selection transistor Trs. As the pixel transistors, in the present embodiment, n-channel MOS transistors are used.

The source of the transfer transistor Trt is connected to the cathode side of the photodiode PD, and the drain thereof is connected to a floating diffusion section FD. Further, a transfer wire, which supplies a transfer pulse φTRG, is connected to a transfer gate electrode 20 between the source and the drain of the transfer transistor Trt. The signal charge (electrons in the present embodiment), which is photoelectrically converted by the photodiode PD and accumulated herein, is transferred to the floating diffusion section FD by applying the transfer pulse φTRG to the transfer gate electrode 20 of the transfer transistor Trt.

The drain of the reset transistor Trr is connected to a power supply voltage VDD, and the source thereof is connected to the floating diffusion section FD. Further, a reset wire, which supplies a reset pulse φRST, is connected to a reset gate electrode 21 between the source and the drain of the reset transistor Trr. Before the transfer of the signal charge from the photodiode PD to the floating diffusion section FD, the reset pulse φRST is applied to the reset gate electrode 21 of the reset transistor Trr. Thereby, the electric potential of the floating diffusion section FD is reset to a VDD level by the power supply voltage VDD.

The drain of the amplification transistor Tra is connected to the power supply voltage VDD, and the source thereof is connected to the drain of the selection transistor Trs. Then, an amplification gate electrode 22 between the source and the drain of the amplification transistor Tra is connected to the floating diffusion section FD. The amplification transistor Tra constitutes a source follower circuit in which the power supply voltage VDD is used as a load, and outputs the pixel signal according to change in the electric potential of the floating diffusion section FD.

The drain of the selection transistor Trs is connected to the source of the amplification transistor Tra, and the source thereof is connected to the vertical signal line 9. Further, a selection wire, which supplies a selection pulse φSEL, is connected to a selection gate electrode 23 between the source and the drain of the selection transistor Trs. By providing the selection pulse φSEL to the selection gate electrode 23 for each pixel, the pixel signal, which is amplified by the amplification transistor Tra, is output to the vertical signal line 9.

In the solid-state imaging apparatus 1 with the above-mentioned configuration, the signal charge, which is accumulated in the photodiode PD by supplying the transfer pulse φTRG to the transfer gate electrode 20, is read by the floating diffusion section FD by the transfer transistor Trt. As the signal charge is read, the electric potential of the floating diffusion section FD is displaced, and change in the electric potential is transferred to the amplification gate electrode 22. Then, the electric potential, which is supplied to the amplification gate electrode 22, is amplified by the amplification transistor Tra, and is selectively output as the pixel signal to the vertical signal line 9 by the selection transistor Trs.

Further, by supplying the reset pulse φRST to the reset gate electrode 21, the signal charge, which is read by the floating diffusion section FD, is reset by the reset transistor Trr so as to be at an electric potential equivalent to the electric potential in the vicinity of the power supply voltage VDD. Then, the pixel signal, which is output to the vertical signal line 9, is thereafter output through the column signal processing circuit 5, the horizontal signal line 10, and the output circuit 7 shown in FIG. 1.

FIG. 3 is a planar layout diagram of a unit pixel according to the present embodiment. In FIG. 3, the transfer transistor Trt is not shown. As shown in FIG. 3, in each pixel 2, the photodiode PD is formed on the central portion thereof. Then, the reset transistor Trr, the amplification transistor Tra, and the selection transistor Trs are successively arranged in this order on one side of the region in which the photodiode PD is formed. Further, the photodiode PD and the active region 39, in which the source and drain regions and the like of the respective pixel transistors are formed, are electrically isolated by a device isolating section 24 which is formed by STI (Shallow Trench Isolation).

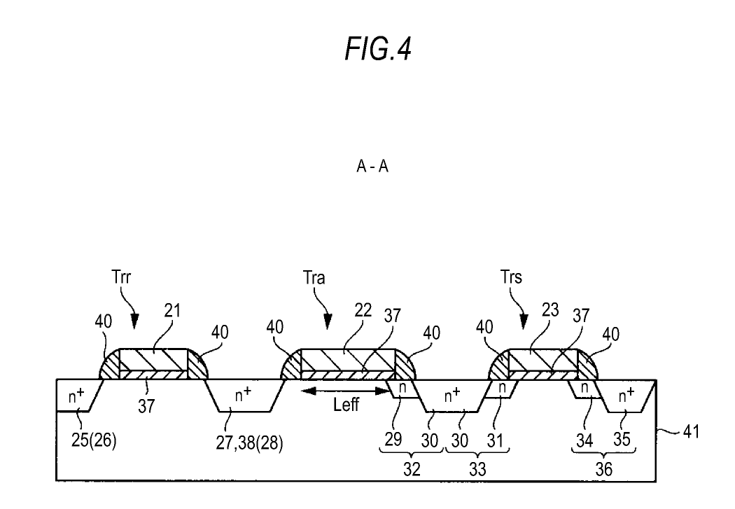

FIG. 4 shows a cross-sectional configuration taken along line A-A of FIG. 3. As shown in FIG. 4, the respective pixel transistors Trr, Tra, and Trs include: source and drain regions 25, 27, 38, 32, 33, and 36 which are formed on the semiconductor substrate 41; and gate electrodes 21, 22, and 23 each of which is formed between the source and the drain thereof. In the present embodiment, in the semiconductor substrate 41, device formation regions, in which the respective pixel transistors Trr, Tra, and Trs are formed, are formed as, for example, p-type semiconductor regions. In addition, the source and drain regions 25, 27, 38, 32, 33, and 36, which constitute the respective pixel transistors Trr, Tra, and Trs, are formed as n-type impurity regions of which a conductivity type is inverse to that of the device formation region.

The reset transistor Trr includes: the reset gate electrode 21 that is formed above the semiconductor substrate 41; and the source region 25 and the drain region 27 that are formed on substrate regions between which the reset gate electrode 21 is interposed.

The reset gate electrode 21 is made of, for example, polysilicon, and is formed on the surface of the semiconductor substrate 41 with a gate insulation film 37 formed of a silicon oxide film and interposed therebetween. Further, side walls 40 are formed of insulation films, such as a silicon oxide film or a silicon nitride film, on the sides of the reset gate electrode 21.

The source region 25 and the drain region 27 of the reset transistor Trr are formed as n-type high-concentration impurity regions 26 and 28 of which a conductivity type is inverse to that of the device formation regions formed as the p-type semiconductor regions of the semiconductor substrate 41. The high-concentration impurity regions 26 and 28 are formed as impurity regions of which the impurity concentration is higher than that of the low-concentration impurity regions for constituting an LDD (Lightly Doped Drain) structure to be described later.

In the following description, regions with the impurity concentration equal to that of the high-concentration impurity regions 26 and 28 are referred to as “high-concentration impurity regions”, and n-type impurity regions, which are formed to have the impurity concentration lower than that of the high-concentration impurity regions, are referred to as “low-concentration impurity regions”.

The amplification transistor Tra includes: the amplification gate electrode 22 which is formed above the semiconductor substrate 41, and the source region 32 and the drain region 38 which are formed on substrate regions between which the amplification gate electrode 22 is interposed.

The amplification gate electrode 22 is formed of, for example, polysilicon, and is formed on the surface of the semiconductor substrate 41 with the gate insulation film 37 formed of silicon oxide film and interposed therebetween. Further, the side walls 40 are formed of insulation films, such as a silicon oxide film and a silicon nitride film, on the sides of the amplification gate electrode 22.

Further, the source region 32 of the amplification transistor Tra includes the low-concentration impurity region 29 and the high-concentration impurity region 30 which are formed in order from the amplification gate electrode 22 side.

On the other hand, the drain region 38 of the amplification transistor Tra includes the high-concentration impurity region 28 in common with the drain region 27 of the reset transistor Trr. That is, the drain region 38 of the amplification transistor Tra also serves as the drain region 27 of the reset transistor.

The selection transistor Trs includes: the selection gate electrode 23 that is formed above the semiconductor substrate 41; and the source region 36 and the drain region 33 that are formed on substrate regions between which the selection gate electrode 23 is interposed.

The selection gate electrode 23 is made of, for example, polysilicon, and is formed on the surface of the semiconductor substrate 41 with the gate insulation film formed of a silicon oxide film and interposed therebetween. Further, the side walls 40 are formed of insulation films, such as a silicon oxide film and a silicon nitride film, on the sides of the selection gate electrode 23.

The source region 36 of the selection transistor Trs includes the low-concentration impurity region 34 and the high-concentration impurity region 35 which are formed in order from the selection gate electrode 23 side. Further, the drain region 33 of the selection transistor Trs includes the low-concentration impurity region 31 and the high-concentration impurity region 30 which are formed in order from the selection gate electrode 23 side, and the high-concentration impurity region 30 also serves as the high-concentration impurity region 30 constituting the source region 32 of the amplification transistor Tra.

As described above, in the present embodiment, the source region 25 and the drain region 27 of the reset transistor Trr and the drain region 38 of the amplification transistor Tra are formed in a single drain structure including only the high-concentration impurity region. On the other hand, the source region 32 of the amplification transistor Tra, the source region 36 and the drain region 33 of the selection transistor Trs, are formed in the LDD structure in which they are formed of the high-concentration impurity region and the low-concentration impurity region which is formed between the high-concentration impurity region and the gate electrode.

### [1-3 Manufacturing Method]

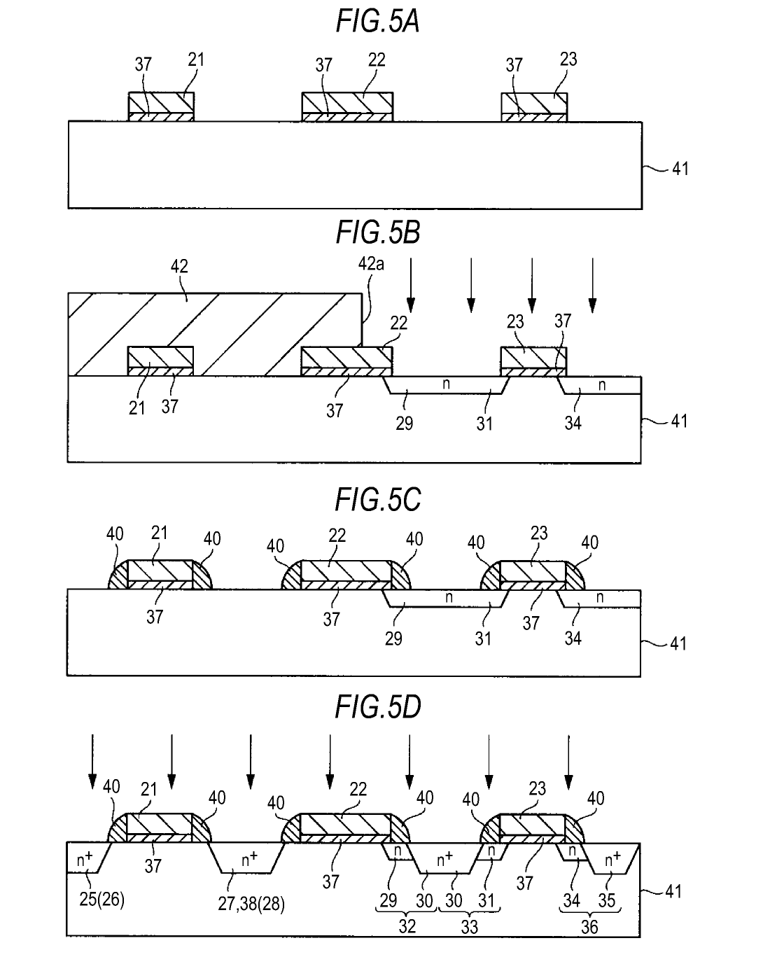

Next, a method of manufacturing the solid-state imaging apparatus according to the present embodiment will be described. FIGS. 5A to 5D are process diagrams illustrating a method of manufacturing a region in which the pixel transistors of the solid-state imaging apparatus 1 according to the present embodiment are formed.

First, as shown in FIG. 5A, the gate insulation film 37 made of a silicon oxide film is formed on the surface of the semiconductor substrate 41, a polysilicon material layer is formed on the gate insulation film 37, and is patterned. Thereby, the reset gate electrode 21, the amplification gate electrode 22, and the selection gate electrode 23 are formed in desired regions on the surface of the semiconductor substrate 41, with the gate insulation film 37 interposed therebetween.

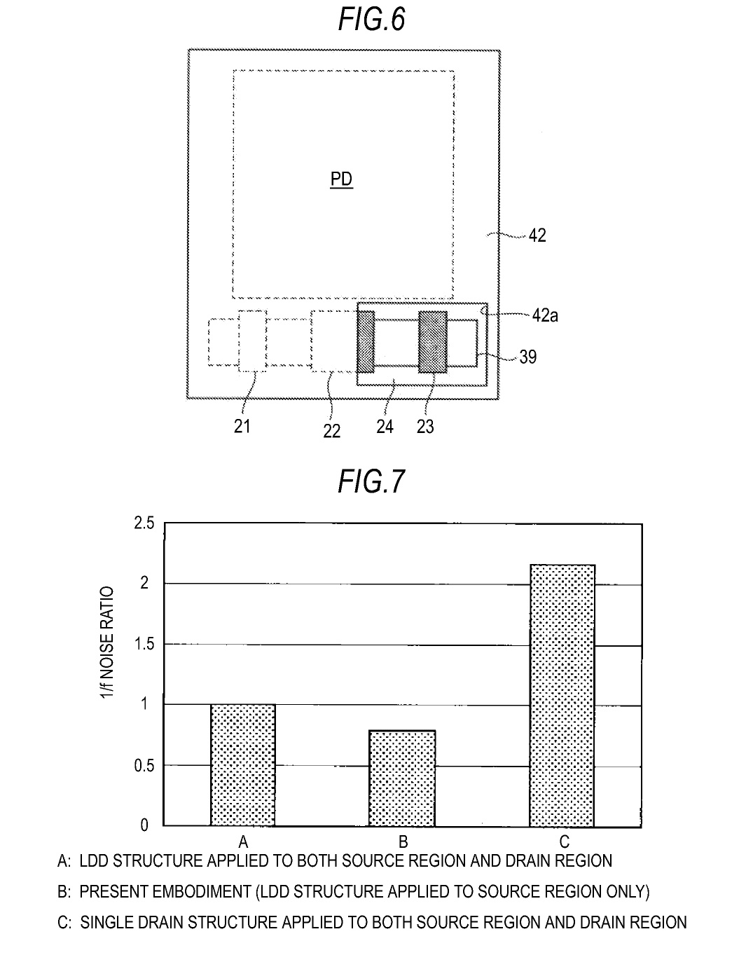

Next, as shown in FIG. 5B, a resist mask 42 is formed on the surface side of the semiconductor substrate such that an opening portion 42a, which opens the source side of the amplification gate electrode 22 (the drain side of the selection gate electrode 23) and the source side of the selection gate electrode 23, is formed thereon. FIG. 6 shows a diagram of a planar configuration in a case where the resist mask 42 is formed on the semiconductor substrate 41. As shown in FIG. 6, the end portion of the opening portion 42a of the resist mask 42 on the source side of the amplification gate electrode 22 is positioned above the amplification gate electrode 22. Further, the end portion of the opening portion 42a of the resist mask 42 on the source side of the selection gate electrode 23 is positioned above the device isolating section 24 which is formed to surround the active region 39 of the pixel transistors.

Next, by using the resist mask 42 as a mask, n-type impurities are ion-implanted at a low concentration. Thereby, the low-concentration impurity regions 29, 31, and 34 are formed on the source side of the amplification gate electrode 22 and the source and drain sides of the selection gate electrode 23. Here, the low-concentration impurity regions 29, 31, and 34 are formed by self-alignment using the respective electrodes as masks at the end portions of the source side of the amplification gate electrode 22 and the drain and source sides of the selection gate electrode 23. Further, due to diffusion of impurities, each of the low-concentration impurity regions 29, 31, and 34 is formed to slightly overflow under each gate electrode.

Next, removing the resist mask 42, as shown in FIG. 5C, the side walls 40 formed of the insulation film are formed on the sides of the respective gate electrodes. The side walls 40 are formed of, for example, the silicon oxide film, the silicon nitride film, or other such laminated films.

Next, after formation of the resist mask in which the regions having the respective pixel transistors formed therein are open, as shown in FIG. 5D, n-type impurities are ion-implanted at a concentration higher than that of the low-concentration impurity regions 29, 31, and 34 which are formed through the previous process. Thereby, the high-concentration impurity regions 26, 28, 30, and 35 are formed. The high-concentration impurity regions 26, 28, 30, and 35 are formed by self-alignment using the side walls 40 as masks on the source and drain sides of the respective gate electrodes. Further, due to diffusion of impurities, each of the high-concentration impurity regions 26, 28, 30, and 35 is formed to slightly overflow under each side wall 40.

Thereafter, by forming the photodiode PD and the like through ion implantation, the solid-state imaging apparatus 1 according to the present embodiment is formed. Further, although not shown in the drawing, the transfer transistor Trt is also formed through the same process as that of the other pixel transistors.

As described above, in the source and drain regions forming the LDD structure, the low-concentration impurity regions formed under the side walls and the high-concentration impurity regions formed in regions which are separated from the gate electrodes and between which the low-concentration impurity regions are interposed. Further, the source and drain regions forming the single drain structure are formed of only the high-concentration impurity regions which are formed by ion implantation after formation of the side walls.

Incidentally, in the solid-state imaging apparatus 1, the 1/f noise, which is proportional to the frequency generated by the amplification transistor Tra, can be reduced by increasing the gate length and increasing the gate width.

In the present embodiment, in the amplification transistor Tra, the drain region 38 has the single drain structure in which the region includes only the high-concentration impurity region 28, and the source region 32 has the LDD structure in which the region includes the low-concentration impurity region 29 and the high-concentration impurity region 30. Hence, compared with the gate length L (FIG. 23) of the existing amplification transistor in which both the source and drain regions have the LDD structures, when the area of the amplification gate electrode is set to be the same, an effective gate length Leff (FIG. 4) of the amplification transistor Tra according to the present embodiment is set to be larger. Thereby, without changing the size of the amplification gate electrode 22, it is possible to improve noise characteristics.

FIG. 7 shows an experimental result of comparison of 1/f noises obtained when the configurations of the source and drain regions of the amplification transistor Tra are respectively changed. A in FIG. 7 represents the examination result of the 1/f noise of the solid-state imaging apparatus obtained in a case of the existing structure in which both source and drain regions of the amplification transistor have the LDD structure. Further, B in FIG. 7 represents the examination result of the 1/f noise of the solid-state imaging apparatus 1 obtained in the case of the structure of the present embodiment in which the drain side has the single drain structure and the source side has the LDD structure. Further, C in FIG. 7 represents the examination result of the 1/f noise of the solid-state imaging apparatus obtained in the case where both source and drain regions of the amplification transistor have the single drain structure.

When the 1/f noise of the existing amplification transistor was set to 1, in the amplification transistor Tra (B in FIG. 7) of the present embodiment, the 1/f noise could be reduced to 0.8. On the other hand, in order to further increase the gate length beyond that of the solid-state imaging apparatus according to the present embodiment, in the case (C in FIG. 7) where both source and drain regions have the single drain structure, the 1/f noise deteriorates to be greater than or equal to twice that of the existing amplification transistor. It can be inferred that the noise, which is generated by the amplification transistor is particularly affected by potential fluctuation between the gate and the source. In C in FIG. 7, it can be inferred that an increase in noise is caused by potential fluctuation due to the trap or the level of the interface under the side wall as the source side of the amplification transistor. Accordingly, it would appear that the low-concentration impurity region on the source side of the amplification transistor Trs is necessary.

As described above, in the present embodiment, the source side of the amplification transistor is configured to have the LDD structure, and thus random noise caused by the potential fluctuation in the vicinity of the source is suppressed. Furthermore, by forming the drain side of the amplification transistor in the single drain structure, it is possible to increase the effective gate length, and thus it is possible to reduce the 1/f noise and RTS (Random Telegraph Signal).

Meanwhile, when only the drain region 38 of the amplification transistor Tra has the single drain structure, the pattern of the resist mask for forming the low-concentration impurity region 29 is miniaturized. In contrast, in the present embodiment, by forming the reset transistor Trr disposed on the drain side of the amplification gate electrode 22 in the single drain structure, the selection transistor Trs disposed on the source side of the amplification gate electrode 22 is configured to have the LDD structure. Accordingly, the resist mask 42, which is used when the low-concentration impurity region 29 is formed, may cover the drain side of the amplification gate electrode 22, and may be patterned such that the source side thereof is open. Hence, compared with the case where the low-concentration impurity region is formed on only the source side of the amplification gate electrode 22, it becomes easy to form the pattern of the resist mask, and it becomes easy to perform processing thereon.

Further, in the solid-state imaging apparatus 1 according to the present embodiment, the source region 32 of the amplification transistor Tra includes the low-concentration impurity region 29 and the high-concentration impurity region 30, but the high-concentration impurity region 30 may not necessarily be formed.

Hereinafter, as a modified example of the present embodiment, the source region of the amplification transistor Tra and the drain region of the selection transistor Trs are formed of only the low-concentration impurity regions.

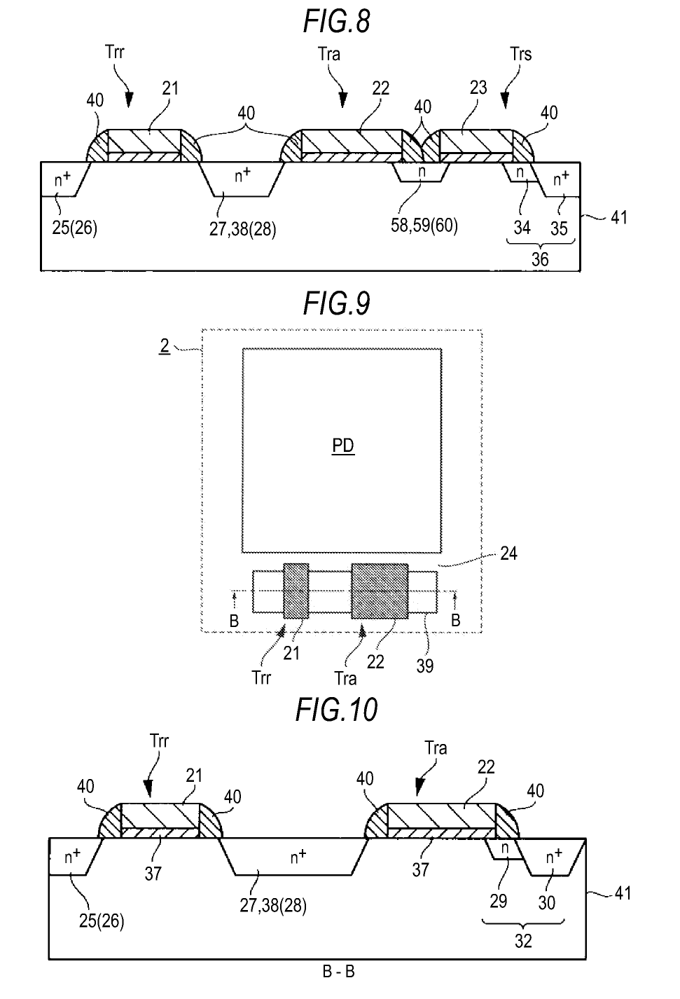

FIG. 8 is a cross-sectional configuration diagram of a solid-state imaging apparatus according to a modified example. FIG. 8 is a diagram corresponding to the cross-sectional configuration taken along line A-A of the planar configuration shown in FIG. 3. In FIG. 8, the portions corresponding to those of FIG. 4 are represented by the same reference numerals and signs, and repeated description will be omitted.

The modified example described herein is an example of a configuration in which a reduction in size of the pixel region causes a decrease in space between the amplification gate electrode 22 and the selection gate electrode 23. In the solid-state imaging apparatus, the source side of the amplification transistor Tra may be connected to the drain side of the selection transistor Trs, and the electrodes not be formed between the amplification gate electrode 22 and the selection gate electrode 23. Accordingly, in the case of a reduction in the area of the pixel transistors caused by a reduction in size of the pixel region, the space between the amplification gate electrode 22 and the selection gate electrode 23 is decreased, and the gate length of the amplification transistor is increased, whereby it is possible to improve noise characteristics.

However, as shown in FIG. 8, by decreasing the space between the amplification gate electrode 22 and the selection gate electrode 23, the side walls 40, which are formed on each gate electrode, may fill up the space between the gate electrodes. In such a case, the high-concentration impurity regions, which are formed by ion implantation after formation of the side walls 40, are not formed on the source side of the amplification gate electrode 22 and the drain side of the selection gate electrode 23.

Accordingly, in the solid-state imaging apparatus according to the modified example, as shown in FIG. 8, the source region 58 of the amplification transistor Tra and the drain region 59 of the selection transistor Trs are formed of only the low-concentration impurity regions 60 which are formed before the formation of the side walls 40.

In such a modified example, by forming the source side of the amplification transistor Tra as the low-concentration impurity region 60, it is possible to reduce noise caused by potential fluctuation of the source side of the amplification transistor Tra. Further, it is possible to reduce the 1/f noise caused by an increase in effective gate length resulting from the formation of the drain side of the amplification transistor Tra formed of only the high-concentration impurity region 28.

### 2. Second Embodiment: Solid-State Imaging Apparatus

Next, a solid-state imaging apparatus according to a second embodiment of the present disclosure will be described. The overall configuration of the solid-state imaging apparatus according to the present embodiment is the same as that of FIG. 1, and thus repeated description thereof will be omitted. Further, the solid-state imaging apparatus according to the present embodiment is different from the solid-state imaging apparatus 1 according to the first embodiment in that the selection transistor Trs is not formed. Accordingly, in an equivalent circuit constituting the pixels 2, the source of each amplification transistor Tra is connected to the vertical signal line 9.

FIG. 9 shows a planar layout diagram of a unit pixel of the solid-state imaging apparatus according to the present embodiment, and FIG. 10 shows a cross-sectional configuration taken along line B-B of FIG. 9. In FIGS. 9 and 10, the transfer transistor is not shown. In FIGS. 9 and 10, the portions corresponding to those of FIGS. 3 and 4 are represented by the same reference numerals and signs, and repeated description thereof will be omitted.

In the present embodiment, as shown in FIG. 3, the reset transistor Trr and the amplification transistor Tra are successively disposed in this order on one side of the photodiode PD.

In the present embodiment, the source region 32 of the amplification transistor Tra includes the low-concentration impurity region 29 and the high-concentration impurity region 30 which are formed in order from the amplification gate electrode 22 side. Further, the drain region 38 of the amplification transistor Tra includes the high-concentration impurity region 28 which also serves as the drain region 27 of the reset transistor Trr.

Further, the source region 25 and the drain region 27 of the reset transistor Trr are respectively formed of only the high-concentration impurity regions 26 and 28. That is, in the present embodiment, only the source region of the amplification transistor Tra has the LDD structure, and the drain region 38 of the amplification transistor Tra and the source region 25 and the drain region 27 of the reset transistor Trr have the single drain structure.

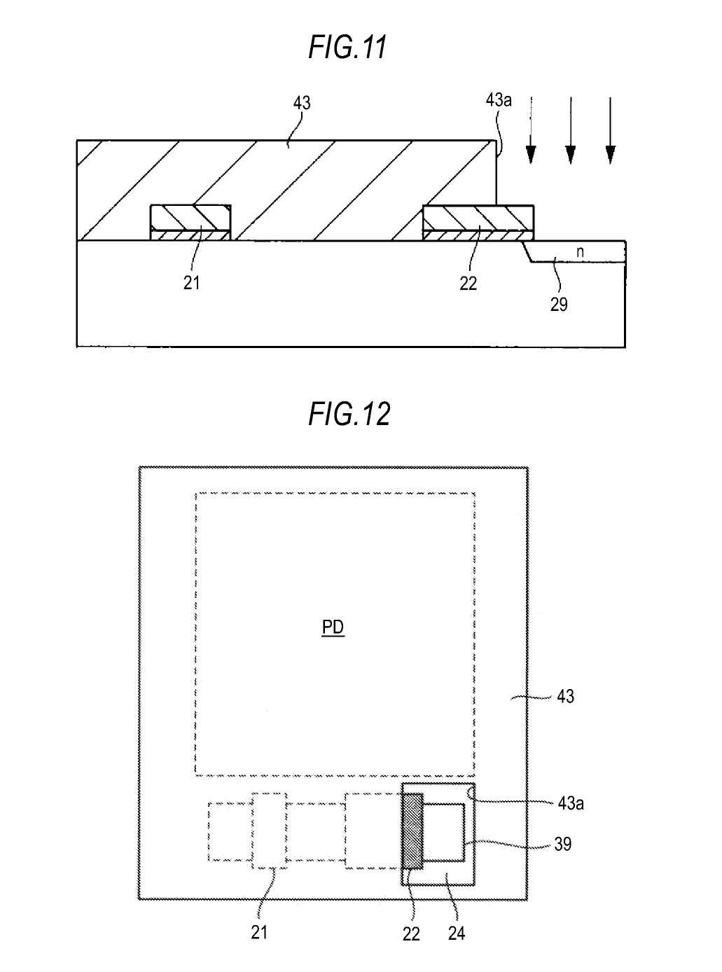

FIG. 11 is a manufacturing process diagram illustrating the method of manufacturing the solid-state imaging apparatus according to the present embodiment. In the present embodiment, after the gate electrodes of the respective pixel transistors are formed on the semiconductor substrate 41, a resist mask 43, which has an opening portion 43a for opening the source side of the amplification gate electrode 22, is formed on the semiconductor substrate 41 including the respective gate electrodes.

FIG. 12 shows a diagram of a planar configuration in a case where the resist mask 43 is formed on the semiconductor substrate 41. As shown in FIG. 12, the end portion of the opening portion 43a of the resist mask 43 on the source side of the amplification gate electrode 22 is positioned above the amplification gate electrode 22. Further, the other end portion of the opening portion 43a is positioned above the device isolating section 24 which is formed to surround the active region 39 of the pixel transistors.

Then, by using the resist mask 43 as a mask, n-type impurities are ion-implanted at a low concentration, whereby the low-concentration impurity region 29 is formed on the source side of the amplification gate electrode 22. At this time, the low-concentration impurity region 29 is formed on the amplification gate electrode 22 side by self-alignment using the amplification gate electrode 22 as the mask.

Thereafter, similarly to FIGS. 5C and 5D, the respective pixel transistors are formed by forming the side walls 40 and the high-concentration impurity regions 26, 28, and 30.

In the present embodiment, in the amplification transistor Tra, the source region 32 has the LDD structure in which the region includes the low-concentration impurity region 29 and the high-concentration impurity region 30, and the drain region 38 has the single drain structure in which the region includes only the high-concentration impurity region 28. Hence, without changing the size of the amplification gate electrode 22, the 1/f noise is reduced. Otherwise, it is possible to obtain the effect the same as that of the first embodiment.

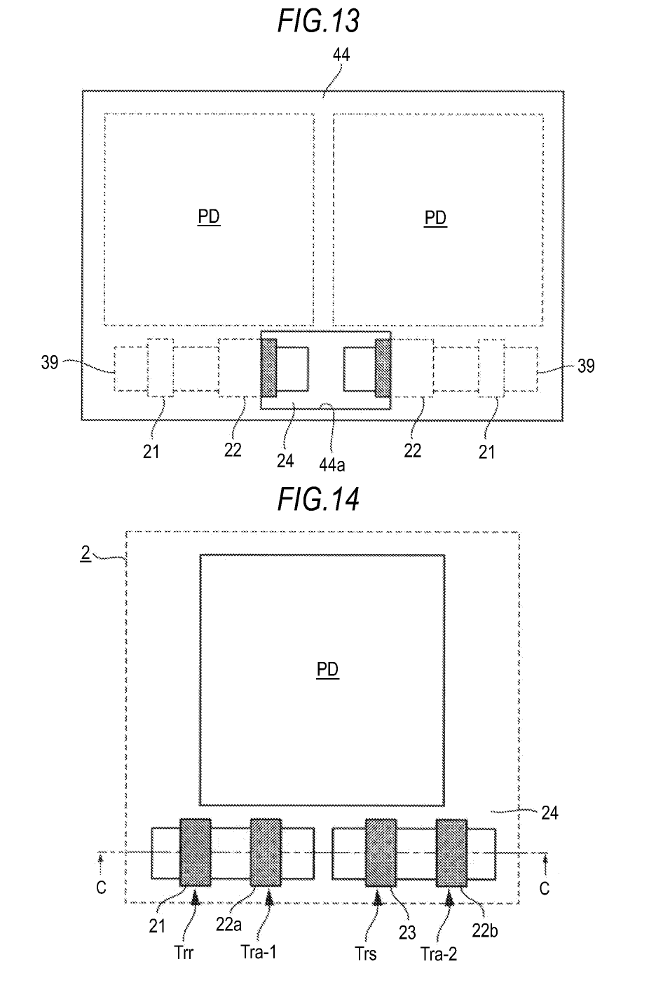

Incidentally, when the opening portion 43a is miniaturized, it is difficult to process the resist mask which is used when the low-concentration impurity region 29 is formed. Accordingly, it is preferable to increase the opening area of the resist mask 43. FIG. 13 shows an example of a layout for widening the opening area of the opening portion of the resist mask in the solid-state imaging apparatus according to the present embodiment.

As shown in FIG. 13, two pixels 2 adjacent to each other in the horizontal direction are configured such that the respective pixel transistors are arranged to be symmetric to each other. In such a manner, in the two adjacent pixels, the source regions 32 of the amplification transistors Tra are adjacent to each other. Accordingly, as shown in FIG. 13, the opening portion 44a of the resist mask 44, which is used when the low-concentration impurity region 29 is formed, can be formed over two pixels. From this result, compared with the opening portion 43a of the resist mask 43 in a case where the low-concentration impurity region 29 is formed for each pixel shown in FIG. 12, it becomes easy to form the pattern of the resist, and it becomes easy to perform processing thereon.

### 3. Third Embodiment: Solid-State Imaging Apparatus

Next, a solid-state imaging apparatus according to a third embodiment of the present disclosure will be described. The overall configuration of the solid-state imaging apparatus according to the present embodiment is the same as that of FIG. 1, and thus repeated description thereof will be omitted. Further, the solid-state imaging apparatus according to the present embodiment is different from the solid-state imaging apparatus according to the first embodiment in that two amplification transistors are formed for each pixel. Accordingly, in an equivalent circuit constituting the pixels, the two amplification transistors are connected to the floating diffusion section FD, the source of each amplification transistor is connected to the drain of the selection transistor, and the drain of each amplification transistor is connected to the drain of the reset transistor.

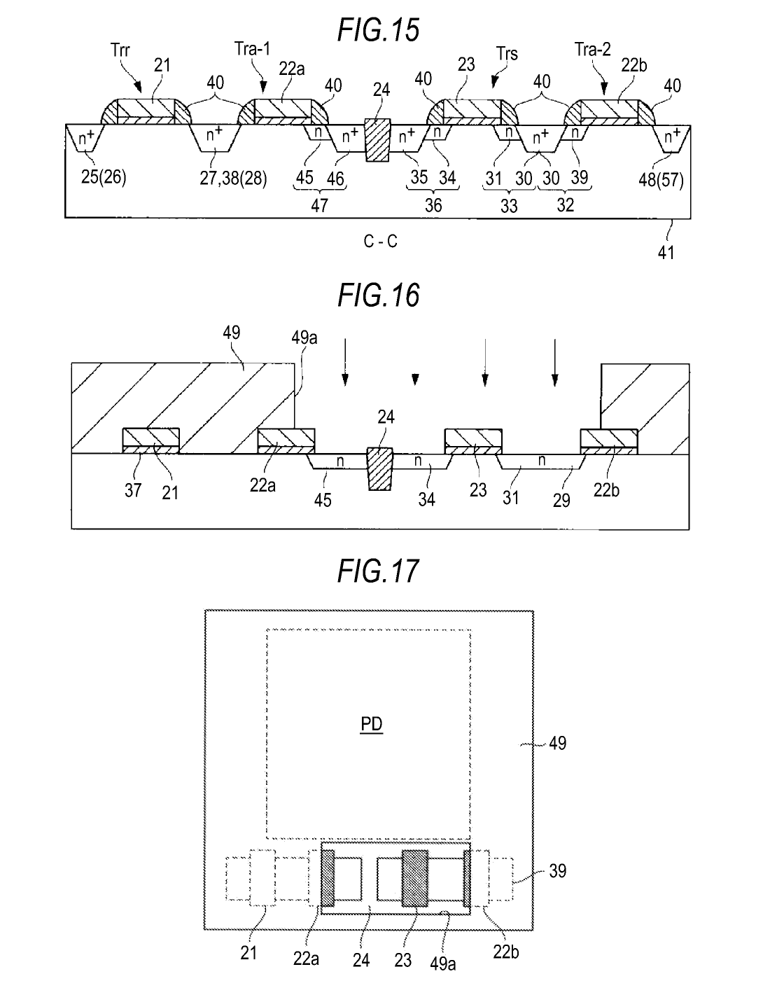

FIG. 14 shows a planar layout diagram of a unit pixel 2 of the solid-state imaging apparatus according to the present embodiment, and FIG. 15 shows a cross-sectional configuration taken along line C-C of FIG. 14. In FIGS. 14 and 15, the transfer transistor is not shown. In FIGS. 14 and 15, the portions corresponding to those of FIGS. 3 and 4 are represented by the same reference numerals and signs, and repeated description thereof will be omitted.

As shown in FIG. 14, in the present embodiment, the reset transistor Trr, a first amplification transistor Tra-1, the selection transistor Trs, and a second amplification transistor Tra-2 are successively arranged in this order on one side of the photodiode PD.

The first amplification transistor Tra-1 includes a first amplification gate electrode 22a that is formed above the semiconductor substrate 41 with the gate insulation film 37 interposed therebetween; and a source region 47 and a drain region 38 that are formed on the regions between which the first amplification gate electrode 22a is interposed. The source region 47 of the first amplification transistor Tra-1 includes a low-concentration impurity region 45 and a high-concentration impurity region 46 which are formed in order from the first amplification gate electrode 22a side. Further, the drain region 38 includes the high-concentration impurity region 28 which also serves as the drain region 27 of the reset transistor Trr.

The second amplification transistor Tra-2 includes: a second amplification gate electrode 22b that is formed above the semiconductor substrate 41 with the gate insulation film 37 interposed therebetween; and the source region 32 and a drain region 48 that are formed in regions between which the second amplification gate electrode 22b is interposed. The source region 32 of the second amplification transistor Tra-2 includes the low-concentration impurity region 29 and the high-concentration impurity region 30 which are formed in order from the second amplification gate electrode 22b side. Further, the drain region 48 includes only the high-concentration impurity region 57.

Then, the high-concentration impurity region 30 constituting the source region 32 of the second amplification transistor Tra-2 also serves as the high-concentration impurity region 30 constituting the drain region 33 of the selection transistor Trs. Further, the source region 36 of the selection transistor Trs and the source region 47 of the first amplification transistor Tra-2 are electrically isolated by the device isolating section 24 formed by STI.

In the present embodiment, the source regions 47 and 32 of the first and second amplification transistors Tra-1 and Tra-2 and the source region 36 and the drain region 33 of the selection transistor Trs have the LDD structure. Further, the drain regions 38 and 48 of the first and second amplification transistors Tra-1 and Tra-b and the source region 25 and the drain region 27 of the reset transistor Trr have the single drain structure.

FIG. 16 is a manufacturing process diagram illustrating the method of manufacturing the solid-state imaging apparatus according to the present embodiment. In the present embodiment, the process, which is performed until the gate electrodes of the respective pixel transistors are formed, is the same as that of FIG. 5A, and thus the description thereof will be omitted. After the respective gate electrodes are formed, as shown in FIG. 16, a resist mask 49 having a desired opening portion 49a is formed on the semiconductor substrate 41 including the respective gate electrodes. In the present embodiment, the opening portion 49a is formed such that the regions on the source sides of the first and second amplification transistors Tra-1 and Tra-2 and the regions on the source and drain sides of the selection transistor Trs are open.

FIG. 17 shows a diagram of a planar configuration in a case where the resist mask 49 is formed on the semiconductor substrate 41. As shown in FIG. 17, the end portion of the opening portion 49a of the resist mask 49 on the source side of the first amplification gate electrode 22a is positioned above the first amplification gate electrode 22a. Likewise, the end portion of the opening portion 49a of the resist mask 49 on the source side of the second amplification gate electrode 22b is positioned above the second amplification gate electrode 22b. Further, the other end portion of the opening portion 49a is positioned above the device isolating section 24 which is formed to surround the active region 39 of the pixel transistors.

Then, by using the resist mask 49 as a mask, n-type impurities are ion-implanted at a low concentration. Thereby, the low-concentration impurity regions 45, 29, 34, and 31 are formed on the source side of the first amplification gate electrode 22a, the source side of the second amplification gate electrode 22b, and the source and drain sides of the selection gate electrode 23. At this time, each low-concentration impurity region is formed by self-alignment using each gate electrode as a mask.

Thereafter, similarly to FIGS. 5C and 5D, the side walls 40 and the high-concentration impurity regions 26, 28, 46, 35, 30, and 57 are formed, thereby forming the respective pixel transistors.

In the present embodiment, two amplification transistors are arranged in parallel for each pixel. Hence, without decreasing the gate area of the amplification gate electrode by much, it is possible to improve the transconductance gm. Further, when two amplification transistors are arranged in parallel, the source sides of the two amplification transistors may be disposed to be close to each other. Thereby, the opening portion of the resist mask for forming the low-concentration impurity region can be formed to be large, and thus it becomes easy to perform processing thereon.

Otherwise, the present embodiment has the same advantages as the first embodiment.

### 4. Fourth Embodiment: Solid-State Imaging Apparatus

Next, a solid-state imaging apparatus according to a fourth embodiment of the present disclosure will be described. The overall configuration of the solid-state imaging apparatus according to the present embodiment is the same as that of FIG. 1, and thus repeated description thereof will be omitted. Further, the solid-state imaging apparatus according to the present embodiment is different from the solid-state imaging apparatus according to the third embodiment in that the selection transistor is not formed. Accordingly, in an equivalent circuit constituting the pixels, the two amplification transistors are connected to the floating diffusion section FD, the source of each amplification transistor is connected to the vertical signal line 9, and the drain of each amplification transistor is connected to the drain of the reset transistor.

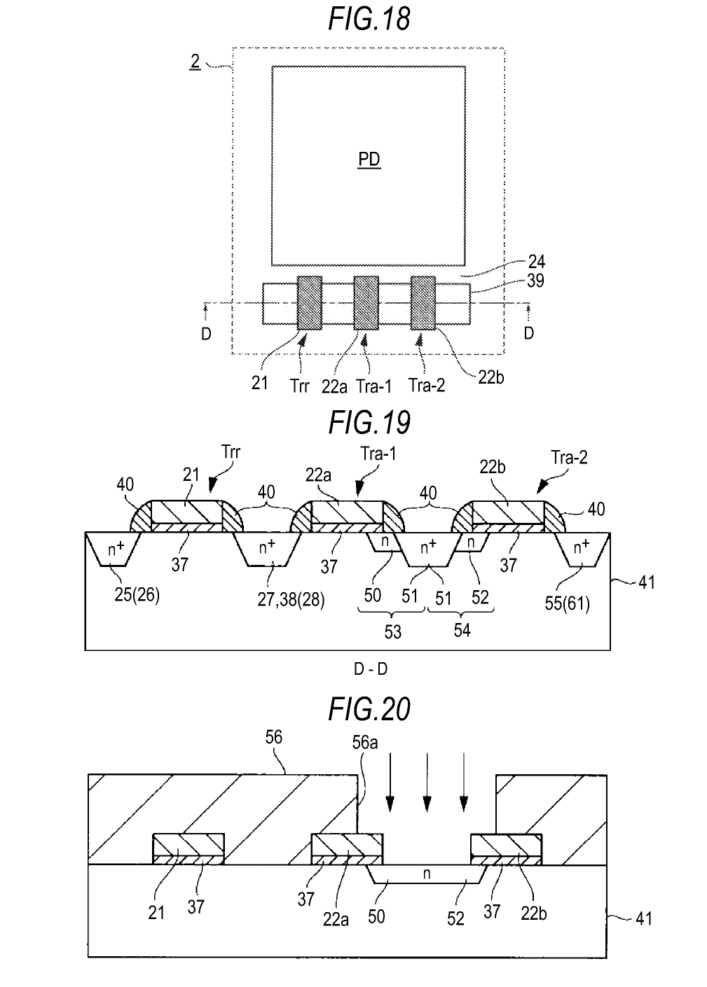

FIG. 18 shows a planar layout diagram of a unit pixel 2 of the solid-state imaging apparatus according to the present embodiment, and FIG. 19 shows a cross-sectional configuration taken along line D-D of FIG. 18. In FIGS. 18 and 19, the transfer transistor is not shown. In FIGS. 18 and 19, the portions corresponding to those of FIGS. 3 and 4 are represented by the same reference numerals and signs, and repeated description thereof will be omitted.

As shown in FIG. 18, in the pixel 2 of the present embodiment, the reset transistor Trr, the first amplification transistor Tra-1, and the second amplification transistor Tra-2 are successively arranged in this order on one side of the photodiode PD.

In the present embodiment, the first amplification transistor Tra-1 includes the first amplification gate electrode 22a that is formed above the semiconductor substrate 41 with the gate insulation film 37 interposed therebetween; and source region 53 and drain region 38 that are formed on the regions between which the first amplification gate electrode 22a is interposed. The source region 53 of the first amplification transistor Tra-1 includes the low-concentration impurity region 50 and the high-concentration impurity region 51 which are formed in order from the first amplification gate electrode 22a side. Further, the drain region 38 includes the high-concentration impurity region 28 which also serves as the drain region 27 of the reset transistor Trr.

The second amplification transistor Tra-2 includes: the second first amplification gate electrode 22b that is formed above the semiconductor substrate 41 with the gate insulation film 37 interposed therebetween; and the source region 54 and the drain region 55 that are formed in regions between which the second first amplification gate electrode 22b is interposed. The source region 54 of the second amplification transistor Tra-2 includes the low-concentration impurity region 52 and the high-concentration impurity region 51 which are formed in order from the second amplification gate electrode 22b side. In addition, the drain region 55 includes only a high-concentration impurity region 61.

Then, the high-concentration impurity region 51 constituting the source region 54 of the second amplification transistor Tra-2 also serves as the high-concentration impurity region 51 constituting the source region 53 of the first amplification transistor Tra-1.

In the present embodiment, the source regions 53 and 54 of the first and second amplification transistors Tra-1 and Tra-2 have the LDD structure. On the other hand, the drain regions 38 and 55 of the first and second amplification transistors Tra-1 and Tra-2 and the source region 25 and the drain region 27 of the reset transistor Trr have the single drain structure.

FIG. 20 is a manufacturing process diagram illustrating the method of manufacturing the solid-state imaging apparatus according to the present embodiment. In the present embodiment, the process, which is performed until the gate electrodes of the respective pixel transistors are formed, is the same as that of FIG. 5A, and thus the description thereof will be omitted. After the respective gate electrodes are formed, as shown in FIG. 20, a resist mask 56 having a desired opening portion 56a is formed on the semiconductor substrate 41 including the respective gate electrodes. In the present embodiment, the opening portion 56a is formed such that the source regions 53 and 54 of the first and second amplification transistors Tra-1 and Tra-2 are open.

FIG. 21 shows a diagram of a planar configuration in a case where the resist mask 56 is formed on the semiconductor substrate 41. As shown in FIG. 21, the end portion of the opening portion 56a of the resist mask 56 on the source side of the first amplification gate electrode 22a is positioned above the first amplification gate electrode 22a. Likewise, the end portion of the opening portion 56a of the resist mask 56 on the source side of the second amplification gate electrode 22b is positioned above the second amplification gate electrode 22b. Further, the other end portion of the opening portion 56a is formed to be positioned above the device isolating section 24 which is formed to surround the active region 39 of the pixel transistors.

Then, by using the resist mask 56 as a mask, n-type impurities are ion-implanted at a low concentration. Thereby, the low-concentration impurity regions 50 and 52 are formed on the source side of the first amplification gate electrode 22a and the source side of the second amplification gate electrode 22b. At this time, the low-concentration impurity regions 50 and 52 are formed on the first and second amplification gate electrodes 22a and 22b by self-alignment using the respective amplification gate electrodes as masks.

Thereafter, similarly to FIGS. 5C and 5D, the side walls 40 and the high-concentration impurity regions 26, 28, 51, and 61 are formed, thereby forming the respective pixel transistors.

In the present embodiment, two amplification transistors are arranged in parallel for each pixel. Hence, without decreasing the gate area of the amplification gate electrode by much, it is possible to improve the transconductance gm. Further, when two amplification transistors are arranged in parallel, the source sides of the two amplification transistors may be disposed to be close to each other. Thereby, the opening portion of the resist mask for forming the low-concentration impurity region can be formed to be large, and thus it becomes easy to perform processing thereon.

Otherwise, the present embodiment has the same advantages as the first embodiment.

The above-mentioned first to fourth embodiments described, as an example of the pixel transistor, the re-channel-type MOS transistor, but the p-channel-type MOS transistor may be used. In the case of using the p-channel-type MOS transistor, in the embodiment of the present disclosure, it is preferable to adopt a configuration in which the conductivity types of the p-type impurity region and n-type impurity region are reversed.

Applications of the present disclosure are not limited to a solid-state imaging apparatus that senses distribution of the amount of incident visible light and captures an image thereof. However, the present disclosure is applicable to a solid-state imaging apparatus that captures an image of distribution of the incident amount of infrared rays, X-rays, particles, or the like. Further, the present disclosure is applicable in a wider sense to general solid-state imaging apparatuses (physical amount distribution sensing apparatuses), such as fingerprint detection sensor, that sense distribution of another physical amount such as a pressure or a capacitance and captures an image thereof.

Furthermore, applications of the present disclosure are not limited to a solid-state imaging apparatus that reads out a pixel signal from each unit pixel by sequentially scanning respective unit pixels in the pixel section row by row. The present disclosure is also applicable to an X-Y address type solid-state imaging apparatus that selects arbitrary pixels pixel by pixel and reads out signals pixel by pixel from the selected pixels.

In addition, the solid-state imaging apparatus may be fabricated in the form of one chip or in the form of a module having an imaging function in which the pixel section and the signal processing section or the optical system are collectively packaged.

Further, applications of the present disclosure are not limited to a solid-state imaging apparatus, and the present disclosure is also applicable to an imaging apparatus. The imaging apparatus described herein include a camera system, such as a digital still camera and a digital video camera, and an electronic apparatus having an imaging function, such as a mobile phone. In addition, the imaging apparatus may also include the module incorporated into an electronic apparatus, that is, a camera module.

### 5. Fifth Embodiment: Electronic Apparatus

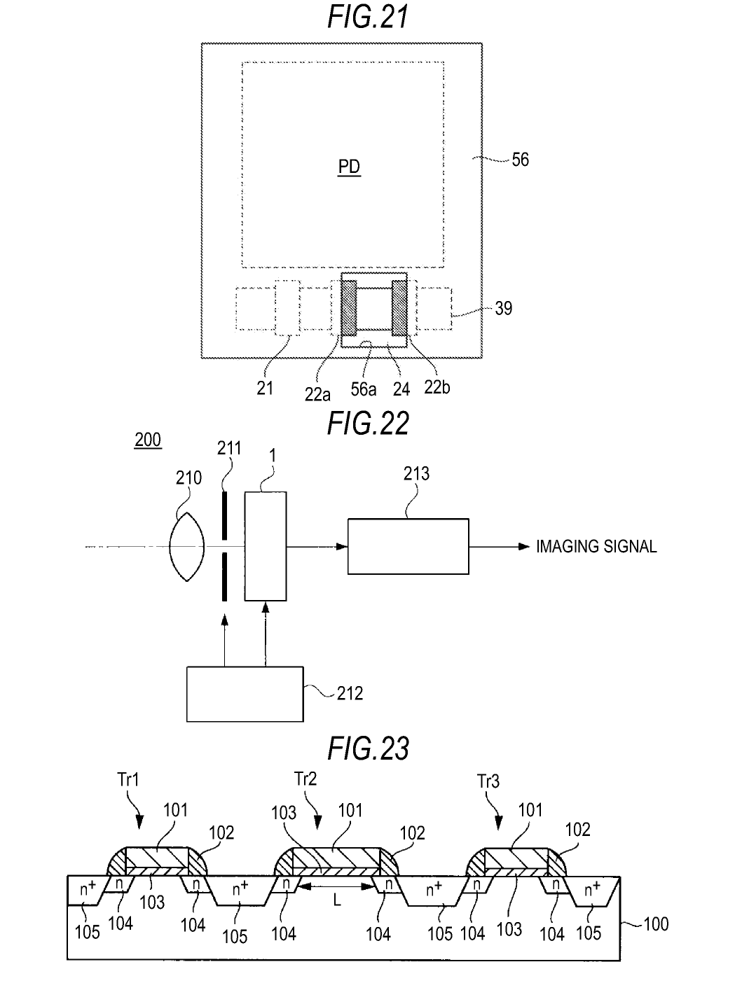

Next, an electronic apparatus according to a fifth embodiment of the present disclosure will be described. FIG. 22 is a schematic configuration diagram of an electronic apparatus 200 according to the fifth embodiment of the present disclosure.

The electronic apparatus 200 according to the present embodiment has the solid-state imaging apparatus 1, an optical lens 210, a shutter device 211, a driving circuit 212, and a signal processing circuit 213. The electronic apparatus 200 according to the present embodiment is an electronic apparatus (camera) using the above-mentioned solid-state imaging apparatus 1 according to the first embodiment.

The optical lens 210 forms an image of light (incident light) from an object on an imaging area of the solid-state imaging apparatus 1. Thereby, signal charges are accumulated in the solid-state imaging apparatus 1 during a certain period.

The shutter device 211 controls a light irradiation period and a light shielding period for the solid-state imaging apparatus 1.

The driving circuit 212 supplies a drive signal that controls a transfer operation of the solid-state imaging apparatus 1 and a shutter operation of the shutter device 211. A signal transfer of the solid-state imaging apparatus 1 is performed in response to the drive signal (timing signal) supplied from the driving circuit 212. The signal processing circuit 213 carries out signal processing of various types. A video signal subjected to the signal processing is stored in a storage medium, such as a memory, or output to a monitor.

In the electronic apparatus 200 according to the present embodiment, noise is reduced in the OB pixel region of the solid-state imaging apparatus 1, and thus image quality is enhanced.

The electronic apparatus 200 to which the solid-state imaging apparatus 1 is applicable is not limited to a camera, and is also applicable to an imaging apparatus, such as a camera module for mobile equipment represented by a mobile phone or the like. Further, in the present embodiment, as a solid-state imaging apparatus constituting the electronic apparatus 200, the solid-state imaging apparatus 1 according to the first embodiment is applied. Otherwise, the solid-state imaging apparatuses according to the second to fourth embodiments may be applied.

The solid-state imaging apparatus, the method of manufacturing the solid-state imaging apparatus, and the electronic apparatus according to the embodiments of the present disclosure have been described hitherto, but various combinations may be made without departing from the scope of the appended claims.

The present disclosure may be implemented as the following configurations.

(1) A solid-state imaging apparatus including:

photoelectric conversion sections that generate signal charge corresponding to an amount of received light; and

a plurality of pixel transistors that read the signal charge generated in the photoelectric conversion sections, and include amplification transistors each being formed of an amplification gate electrode which is formed on a substrate, a high-concentration impurity region which is formed in a substrate region on a drain side of the amplification gate electrode, and a low-concentration impurity region which is formed to have an impurity concentration lower than that of the high-concentration impurity region and is formed on a substrate region on a source side of the amplification gate electrode.

(2) The solid-state imaging apparatus according to (1), wherein the high-concentration impurity region, which is formed to have an impurity concentration higher than that of the low-concentration impurity region, is formed in a substrate region separated from the amplification gate electrode, in substrate regions successive to the low-concentration impurity region, on the source side of the amplification gate electrode.

(3) The solid-state imaging apparatus according to (1) or (2), wherein among the pixel transistors, each reset transistor includes a reset gate electrode which is formed on the substrate, and high-concentration impurity regions which are formed in substrate regions on a source side and a drain side of the reset gate electrode.

(4) The solid-state imaging apparatus according to any one of (1) to (3), wherein among the pixel transistors, each selection transistor includes a selection gate electrode which is formed on the substrate, high-concentration impurity regions which are formed in substrate regions on a source side and a drain side of the selection gate electrode, and low-concentration impurity regions which are formed in substrate regions between the selection gate electrode and the respective high-concentration impurity regions which are formed to have an impurity concentration lower than that of the high-concentration impurity regions and are formed on the source side and the drain side of the selection gate electrode.

(5) The solid-state imaging apparatus according to any one of (1) to (4), wherein the high-concentration impurity region on the source side of each amplification transistor also serves as the high-concentration impurity region on the drain side of the selection transistor.

(6) The solid-state imaging apparatus according to any one of (1) to (4), wherein two amplification transistors are provided for each pixel, and the high-concentration impurity region on the source side of one amplification transistor of the two amplification transistors also serves as the high-concentration impurity region on the drain side of the selection transistor, and the high-concentration impurity region on the drain side of the other amplification transistor also serves as the high-concentration impurity region on the drain side of the reset transistor.

(7) The solid-state imaging apparatus according to any one of (1) to (4), wherein two amplification transistors are provided for each pixel, and the high-concentration impurity region on the source side of one amplification transistor of the two amplification transistors also serves as the high-concentration impurity region on the source side of the other amplification transistor, and the high-concentration impurity region on the drain side of the other amplification transistor also serves as the high-concentration impurity region on the drain side of the reset transistor.

(8) A method of manufacturing a solid-state imaging apparatus including a plurality of pixels formed of photoelectric conversion sections which generate signal charge corresponding to an amount of incident light and a plurality of pixel transistors which read the signal charge generated in the photoelectric conversion sections, the method including:

forming gate electrodes that constitute the plurality of pixel transistors on a substrate;

forming a resist mask that covers substrate regions on drain sides of amplification gate electrodes, which constitute amplification transistors among the plurality of pixel transistors, such that at least substrate regions on source sides of the amplification gate electrodes are open;

forming low-concentration impurity regions by ion-implanting impurity, of which a conductivity type is inverse to that of the substrate, through the resist mask;

forming side walls on sides of the gate electrodes by removing the resist mask; and

forming high-concentration impurity regions, which are impurity regions with a concentration higher than that of the low-concentration impurity regions, by ion-implanting impurity, of which a conductivity type is inverse to that of the substrate, into the substrate regions on the source sides and the drain sides of the gate electrodes constituting the plurality of pixel transistors.

(9) The method of manufacturing the solid-state imaging apparatus according to (8), wherein the resist mask is formed to cover the source side and the drain side of each reset transistor.

(10) The method of manufacturing the solid-state imaging apparatus according to (8) or (9), wherein the resist mask is formed such that the source side and the drain side of each selection transistor are open.

(11) An electronic apparatus including:

an optical lens;

a solid-state imaging apparatus including photoelectric conversion sections that generate signal charge corresponding to an amount of received light, and a plurality of pixel transistors that read the signal charge generated in the photoelectric conversion sections, and include amplification transistors each being formed of an amplification gate electrode which is formed on a substrate, a high-concentration impurity region which is formed in a substrate region on a drain side of the amplification gate electrode, and a low-concentration impurity region which is formed to have an impurity concentration lower than that of the high-concentration impurity region and is formed on a substrate region on a source side of the amplification gate electrode; and a signal processing circuit that processes an output signal which is output from the solid-state imaging apparatus.

The present disclosure contains subject matter related to that disclosed in Japanese Priority Patent Application JP 2011-182429 filed in the Japan Patent Office on Aug. 24, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging apparatus comprising:
photoelectric conversion sections that generate signal charge corresponding to an amount of received light; and
a plurality of pixel transistors that read the signal charge generated in the photoelectric conversion sections, and include amplification transistors each being formed of an amplification gate electrode which is formed on a substrate, a high-concentration impurity region which is formed in a substrate region on a drain side of the amplification gate electrode, and a low-concentration impurity region which is formed to have an impurity concentration lower than that of the high-concentration impurity region and is formed on a substrate region on a source side of the amplification gate electrode.

2. The solid-state imaging apparatus according to claim 1, wherein the high-concentration impurity region, which is formed to have an impurity concentration higher than that of the low-concentration impurity region, is formed in a substrate region separated from the amplification gate electrode, in substrate regions successive to the low-concentration impurity region, on the source side of the amplification gate electrode.

3. The solid-state imaging apparatus according to claim 2, wherein among the pixel transistors, each reset transistor includes a reset gate electrode which is formed on the substrate, and high-concentration impurity regions which are formed in substrate regions on a source side and a drain side of the reset gate electrode.

4. The solid-state imaging apparatus according to claim 3, wherein among the pixel transistors, each selection transistor includes a selection gate electrode which is formed on the substrate, high-concentration impurity regions which are formed in substrate regions on a source side and a drain side of the selection gate electrode, and low-concentration impurity regions which are formed in substrate regions between the selection gate electrode and the respective high-concentration impurity regions which are formed to have an impurity concentration lower than that of the high-concentration impurity regions and are formed on the source side and the drain side of the selection gate electrode.

5. The solid-state imaging apparatus according to claim 4, wherein the high-concentration impurity region on the source side of each amplification transistor also serves as the high-concentration impurity region on the drain side of the selection transistor.

6. The solid-state imaging apparatus according to claim 5, wherein two amplification transistors are provided for each pixel, and the high-concentration impurity region on the source side of one amplification transistor of the two amplification transistors also serves as the high-concentration impurity region on the drain side of the selection transistor, and the high-concentration impurity region on the drain side of the other amplification transistor also serves as the high-concentration impurity region on the drain side of the reset transistor.

7. The solid-state imaging apparatus according to claim 4, wherein two amplification transistors are provided for each pixel, and the high-concentration impurity region on the source side of one amplification transistor of the two amplification transistors also serves as the high-concentration impurity region on the source side of the other amplification transistor, and the high-concentration impurity region on the drain side of the other amplification transistor also serves as the high-concentration impurity region on the drain side of the reset transistor.

8. A method of manufacturing a solid-state imaging apparatus including a plurality of pixels formed of photoelectric conversion sections which generate signal charge corresponding to an amount of incident light and a plurality of pixel transistors which read the signal charge generated in the photoelectric conversion sections, the method comprising:
forming gate electrodes that constitute the plurality of pixel transistors on a substrate;
forming a resist mask that covers substrate regions on drain sides of amplification gate electrodes, which constitute amplification transistors among the plurality of pixel transistors, such that at least substrate regions on source sides of the amplification gate electrodes are open;
forming low-concentration impurity regions by ion-implanting impurity, of which a conductivity type is inverse to that of the substrate, through the resist mask;
forming side walls on sides of the gate electrodes by removing the resist mask; and
forming high-concentration impurity regions, which are impurity regions with a concentration higher than that of the low-concentration impurity regions, by ion-implanting impurity, of which a conductivity type is inverse to that of the substrate, into the substrate regions on the source sides and the drain sides of the gate electrodes constituting the plurality of pixel transistors.

9. The method of manufacturing the solid-state imaging apparatus according to claim 8, wherein the resist mask is formed to cover the source side and the drain side of each reset transistor.

10. The method of manufacturing the solid-state imaging apparatus according to claim 9, wherein the resist mask is formed such that the source side and the drain side of each selection transistor are open.

11. An electronic apparatus comprising:
an optical lens;
a solid-state imaging apparatus including photoelectric conversion sections that generate signal charge corresponding to an amount of received light, and a plurality of pixel transistors that read the signal charge generated in the photoelectric conversion sections, and include amplification transistors each being formed of an amplification gate electrode which is formed on a substrate, a high-concentration impurity region which is formed in a substrate region on a drain side of the amplification gate electrode, and a low-concentration impurity region which is formed to have an impurity concentration lower than that of the high-concentration impurity region and is formed on a substrate region on a source side of the amplification gate electrode; and
a signal processing circuit that processes an output signal which is output from the solid-state imaging apparatus.
